(19) United States
(12) Patent Application Publication
(10) Pub. No.: US 2007/0023839 A1
(43) Pub. Date: Feb. 1, 2007

(54) FINFET GATE FORMED OF CARBON NANOTUBES

(75) Inventors: Toshiharu Furukawa, Essex Junction, VT (US); Mark C. Hakey, Fairfax, VT (US); Steven J. Holmes, Guilderland, NY (US); David V. Horak, Essex Junction, VT (US); Charles W. Koburger III, Delmar, NY (US)

Correspondence Address: FREDERICK W. GIBB, III;GIBB INTELLECTUAL PROPERTY LAW FIRM, LLC, 2568-A RIVA ROAD, SUITE 304, ANNAPOLIS, MD, 21401, US

(73) Assignee: INTERNATIONAL BUSINESS MACHINES CORPORATION, Armonk, NY (US)

(21) Appl. No.: 11/161,219

(22) Filed: Jul. 27, 2005

(51) Int. Cl. H01L 27/12

(52) U.S. Cl. 257/353

(57) ABSTRACT

A fin field effect transistor (FinFET) gate comprises a semiconductor wafer; a gate dielectric layer over the semiconductor wafer; a conductive material on the gate dielectric layer; an activated carbon nanotube on a surface of the conductive material; and a plated metal layer on the activated carbon nanotube. Preferably, the carbon nanotube is on a sidewall of the conductive material. The conductive material comprises a first metal layer over the gate dielectric layer, wherein the first metal layer acts as a catalyst for growing the carbon nanotube, wherein the first metal layer is preferably in a range of 1-10 nm in thickness. The semiconductor wafer may comprise a silicon on insulator wafer. The FinFET gate may further comprise a second metal layer disposed between the first metal layer and the gate dielectric layer.

### BACKGROUND

1. Field of the Invention

The embodiments of the invention generally relate to microelectronic logic devices and methods of fabrication and, more particularly, to the design and manufacturing of integrated circuit devices having fin field effect transistor (FinFET) components.

2. Description of the Related Art

It is often difficult to form gate conductor features on FinFET structures due to the large topography of the fin. If subtractive etch processes are used, very long etch times are typically required, which may introduce variations in the dimensions of the gate conductor itself. Therefore, it is desirable to develop techniques of forming the gate conductor on the FinFETs, which can avoid the requisite long etch times generally found in conventional processes.

### SUMMARY

In view of the foregoing, an embodiment of the invention provides a fin field effect transistor (FinFET) gate comprising a semiconductor wafer; a gate dielectric layer over the semiconductor wafer; a conductive material on the gate dielectric layer; an activated carbon nanotube on a surface of the conductive material; and a plated metal layer on the activated carbon nanotube. Preferably, the carbon nanotube is on a sidewall of the conductive material. The conductive material comprises a first metal layer over the gate dielectric layer, wherein the first metal layer acts as a catalyst for growing the carbon nanotube, wherein the first metal layer is preferably in a range of 1-10 nm in thickness. The semiconductor wafer may comprise a silicon on insulator wafer. The FinFET gate may further comprise a second metal layer disposed between the first metal layer and the gate dielectric layer, wherein the first metal layer may comprise any of Co, Ni, and Fe, and wherein the second metal layer may comprise any of Re, TaN, W, Ru, Pt, Rh, and doped polycrystalline silicon.

Another embodiment of the invention provides a transistor device comprising a semiconductor wafer; a gate dielectric layer over the semiconductor wafer; a conductive material on the gate dielectric layer; an activated carbon nanotube on a surface of the conductive material; a seed metal layer on the activated carbon nanotube; and a plated metal layer on the seed metal layer. Preferably, the carbon nanotube is on a sidewall of the conductive material. The conductive material may comprise a first metal layer over the gate dielectric layer, wherein the first metal layer acts as a catalyst for growing the carbon nanotube. Preferably, the first metal layer is in a range of 1-10 nm in thickness. The semiconductor wafer may comprise a silicon on insulator wafer. The transistor device may further comprise a second metal layer disposed between the first metal layer and the gate dielectric layer, wherein the first metal layer may comprise any of Co, Ni, and Fe, and wherein the second metal layer may comprise any of Re, TaN, W, Ru, Pt, Rh, and doped polycrystalline silicon.

Another aspect of the invention provides a method of forming a gate structure for a semiconductor device, wherein the method comprises forming a gate dielectric layer over a semiconductor wafer; depositing a conductive material on the gate dielectric layer; growing a carbon nanotube on a surface of the conductive material; activating the carbon nanotube; attaching metal ions to the activated carbon nanotube; forming a seed metal layer on the activated carbon nanotube by chemically reducing the metal ions; and plating metal on the seed metal layer. Preferably, the carbon nanotube is formed on a sidewall of the conductive material. The conductive material comprises a first metal layer over the gate dielectric layer, wherein the first metal layer acts as a catalyst for growing the carbon nanotube. The first metal layer is preferably in a range of 1-10 nm in thickness. The method further comprises forming a second metal layer between the first metal layer and the gate dielectric layer, wherein the first metal layer may comprise any of Co, Ni, and Fe, and wherein the second metal layer may comprise any of Re, TaN, W, Ru, Pt, Rh, and doped polycrystalline silicon.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 (A) is a top view illustrating a FinFET gate structure according to an embodiment of the invention;

FIG. 1 (B) is a cross-sectional side view cut along line A-A of FIG. 1 (A) illustrating the FinFET gate structure of FIG. 1 (A) according to an embodiment of the invention;

FIG. 2(A) is a top view illustrating a FinFET gate structure according to an embodiment of the invention;

FIG. 2(B) is a cross-sectional side view cut along line B-B of FIG. 2(A) illustrating the FinFET gate structure of FIG. 2(A) according to an embodiment of the invention;

FIG. 3(A) is a top view illustrating a FinFET gate structure according to an embodiment of the invention;

FIG. 3(B) is a cross-sectional side view cut along line C-C of FIG. 3(A) illustrating the FinFET gate structure of FIG. 3(A) according to an embodiment of the invention;

FIG. 4(A) is a top view illustrating a FinFET gate structure according to a second embodiment of the invention;

FIG. 4(B) is a cross-sectional side view cut along line D-D of FIG. 4(A) illustrating the FinFET gate structure of FIG. 4(A) according to a second embodiment of the invention;

FIG. 5(A) is a top view illustrating a FinFET gate structure according to a first embodiment of the invention;

FIG. 5(B) is a cross-sectional side view cut along line E-E of FIG. 5(A) illustrating the FinFET gate structure of FIG. 5(A) according to a first embodiment of the invention;

FIG. 6(A) is a top view illustrating a FinFET gate structure according to a second embodiment of the invention;

FIG. 6(B) is a cross-sectional side view cut along line F-F of FIG. 6(A) illustrating the FinFET gate structure of FIG. 6(A) according to a second embodiment of the invention;

FIG. 7(A) is a top view illustrating a FinFET gate structure according to a first embodiment of the invention;

FIG. 7(B) is a cross-sectional side view cut along line G-G of FIG. 7(A) illustrating the FinFET gate structure of FIG. 7(A) according to a first embodiment of the invention;

FIG. 8(A) is a top view illustrating a FinFET gate structure according to a second embodiment of the invention;

FIG. 8(B) is a cross-sectional side view cut along line H-H of FIG. 8(A) illustrating the FinFET gate structure of FIG. 8(A) according to a second embodiment of the invention;

FIG. 9(A) is a top view illustrating a FinFET gate structure according to a first embodiment of the invention;

FIG. 9(B) is a cross-sectional side view cut along line I-I of FIG. 9(A) illustrating the FinFET gate structure of FIG. 9(A) according to a first embodiment of the invention;

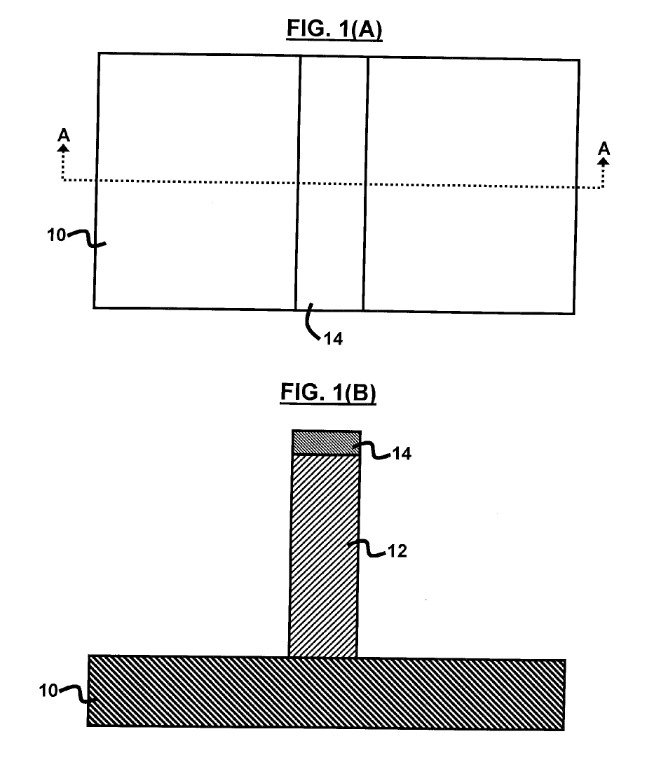

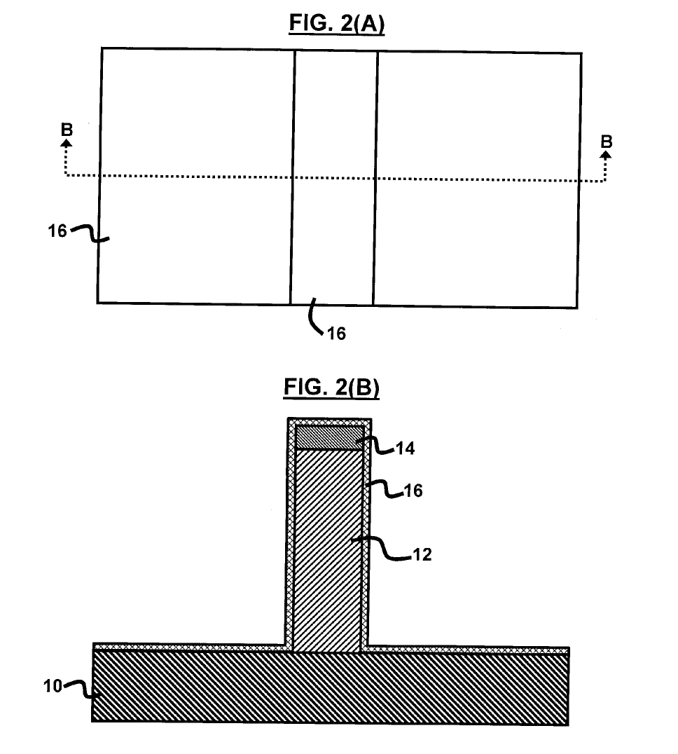

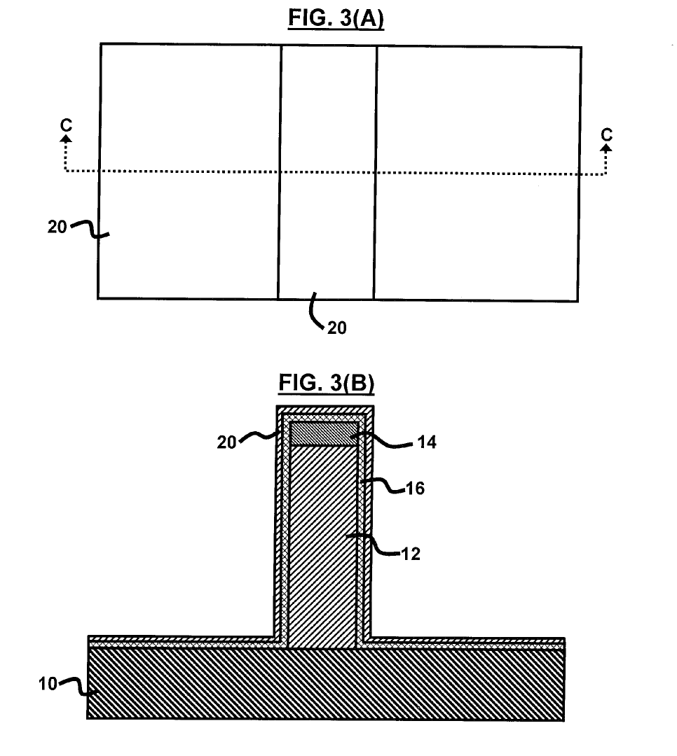

FIG. 1O(A) is a top view illustrating a FinFET gate structure according to a second embodiment of the invention;

FIG. 1O(B) is a cross-sectional side view cut along line J-J of FIG. 1O(A) illustrating the FinFET gate structure of FIG. 1O(A) according to a second embodiment of the invention;

FIG. 11 (A) is a top view illustrating a FinFET gate structure according to an embodiment of the invention;

FIG. 11(B) is a cross-sectional side view cut along line K-K of FIG. 11(A) illustrating the FinFET gate structure of FIG. 11(A) according to an embodiment of the invention;

FIG. 12(A) is a top view illustrating a FinFET gate structure according to a first embodiment of the invention;

FIG. 12(B) is a cross-sectional side view cut along line L-L of FIG. 12(A) illustrating the FinFET gate structure of FIG. 12(A) according to a first embodiment of the invention;

FIG. 13(A) is a top view illustrating a FinFET gate structure according to a second embodiment of the invention;

FIG. 13(B) is a cross-sectional side view cut along line M-M of FIG. 13(A) illustrating the FinFET gate structure of FIG. 13(A) according to a second embodiment of the invention;

FIG. 14(A) is a top view illustrating a FinFET gate structure according to a first embodiment of the invention;

FIG. 14(B) is a cross-sectional side view cut along line N-N of FIG. 14(A) illustrating the FinFET gate structure of FIG. 14(A) according to a first embodiment of the invention;

FIG. 15(A) is a top view illustrating a FinFET gate structure according to a second embodiment of the invention;

FIG. 15(B) is a cross-sectional side view cut along line O-O of FIG. 15(A) illustrating the FinFET gate structure of FIG. 15(A) according to a second embodiment of the invention;

FIG. 16(A) is a top view illustrating a FinFET gate structure according to a first embodiment of the invention;

FIG. 16(B) is a cross-sectional side view cut along line P-P of FIG. 16(A) illustrating the FinFET gate structure of FIG. 16(A) according to a first embodiment of the invention;

FIG. 17(A) is a top view illustrating a FinFET gate structure according to a second embodiment of the invention;

FIG. 17(B) is a cross-sectional side view cut along line Q-Q of FIG. 17(A) illustrating the FinFET gate structure of FIG. 17(A) according to a second embodiment of the invention;

FIG. 18(A) is a top view illustrating a FinFET gate structure according to a first embodiment of the invention;

FIG. 18(B) is a cross-sectional side view cut along line R-R of FIG. 18(A) illustrating the FinFET gate structure of FIG. 18(A) according to a first embodiment of the invention;

FIG. 19(A) is a top view illustrating a FinFET gate structure according to a second embodiment of the invention;

FIG. 19(B) is a cross-sectional side view cut along line S-S of FIG. 19(A) illustrating the FinFET gate structure of FIG. 19(A) according to a second embodiment of the invention;

FIG. 20(A) is a top view illustrating a FinFET gate structure according to a first embodiment of the invention;

FIG. 20(B) is a cross-sectional side view cut along line T-T of FIG. 20(A) illustrating the FinFET gate structure of FIG. 20(A) according to a first embodiment of the invention;

FIG. 21(A) is a top view illustrating a FinFET gate structure according to a second embodiment of the invention;

FIG. 21(B) is a cross-sectional side view cut along line U-U of FIG. 21(A) illustrating the FinFET gate structure of FIG. 21(A) according to a second embodiment of the invention;

FIG. 22(A) is a top view illustrating a FinFET gate structure according to a first embodiment of the invention;

FIG. 22(B) is a cross-sectional side view cut along line V-V of FIG. 22(A) illustrating the FinFET gate structure of FIG. 22(A) according to a first embodiment of the invention;

FIG. 23(A) is a top view illustrating a FinFET gate structure according to a second embodiment of the invention;

FIG. 23(B) is a cross-sectional side view cut along line W-W of FIG. 23(A) illustrating the FinFET gate structure of FIG. 23(A) according to a second embodiment of the invention;

FIG. 24(A) is a top view illustrating a FinFET gate structure according to a first embodiment of the invention;

FIG. 24(B) is a cross-sectional side view cut along line X-X of FIG. 24(A) illustrating the FinFET gate structure of FIG. 24(A) according to a first embodiment of the invention;

FIG. 25(A) is a top view illustrating a FinFET gate structure according to a second embodiment of the invention; and

FIG. 25(B) is a cross-sectional side view cut along line Y-Y of FIG. 25(A) illustrating the FinFET gate structure of FIG. 25(A) according to a second embodiment of the invention.

### DETAILED DESCRIPTION OF PREFERRED EMBODIMENTS OF THE INVENTION

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned, there remains a need for novel techniques of forming the gate conductor on the FinFETs, which can avoid the requisite long etch times generally found in conventional processes. The embodiments of the invention achieve this by providing a FinFET gate structure formed of carbon nanotubes. Referring now to the drawings and more particularly to FIGS. 1 through 25(B) where similar reference characters denote corresponding features consistently throughout the figures, there are shown preferred embodiments of the invention.

As shown in FIGS. 1(A) and 1(B), a silicon on insulator (SOI) wafer is prepared by forming a silicon fin 12 (which shall eventually act as the FinFET channel region) over a buried oxide (BOX) layer 10 of a SOI wafer, which are formed over an underlying substrate (not shown). Silicon dioxide or silicon nitride is formed on the top surface of SOI wafer before the silicon fin 12 is etched so that a thin cap layer 14 of nitride or silicon dioxide is formed over the silicon fin 12.

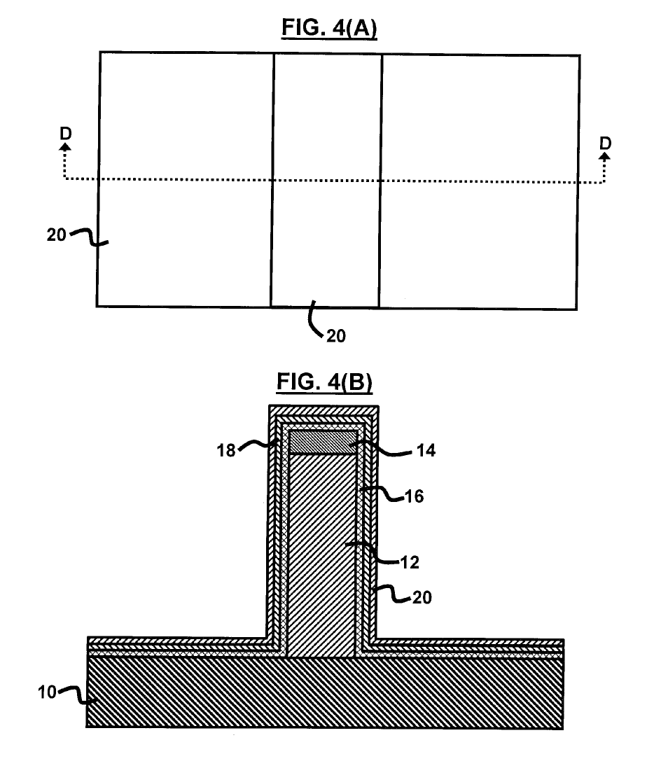

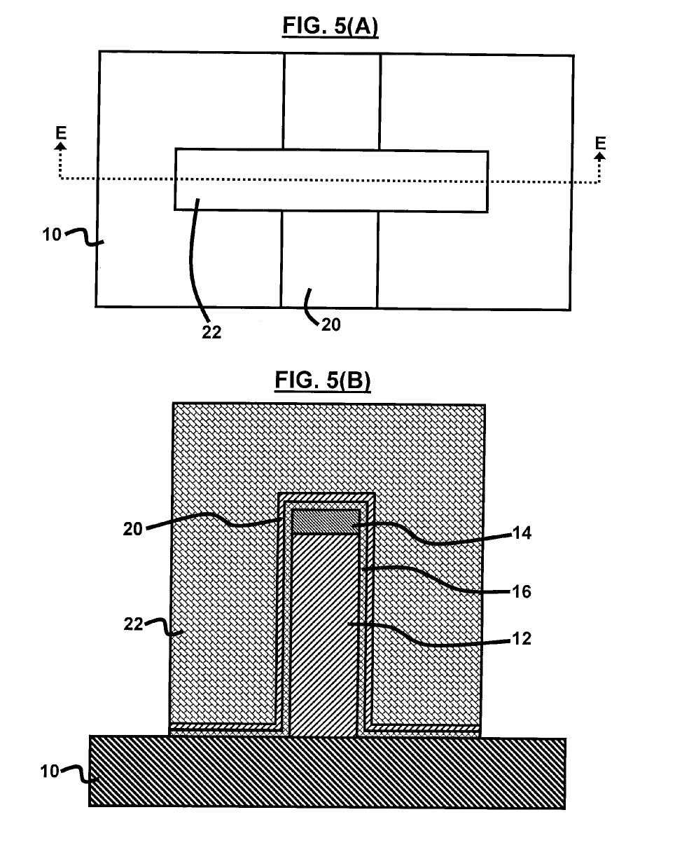

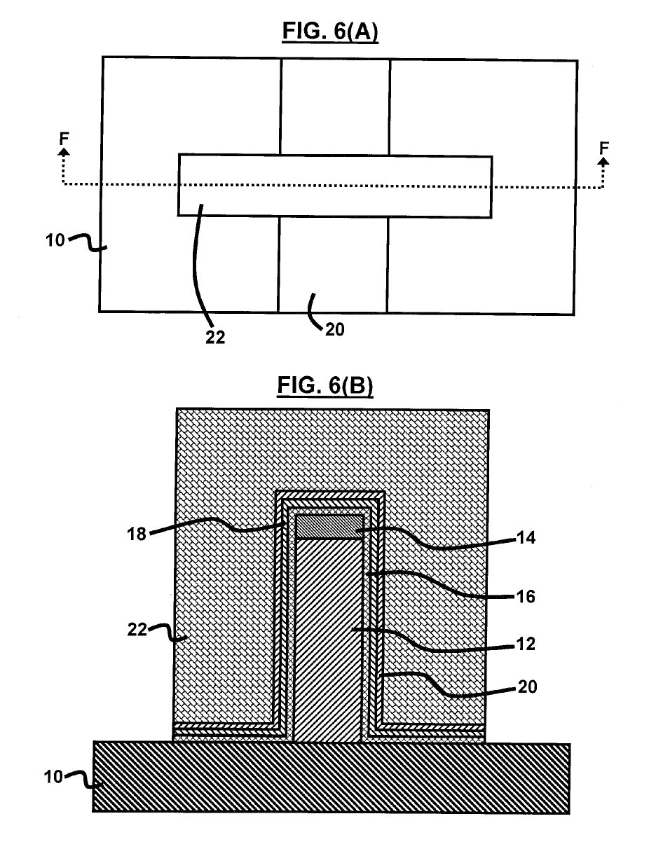

Next, as shown in FIGS. 2(A) and 2(B), a thin (approximately 1-3 nm) gate dielectric layer 16, such as a silicon dioxide, silicon oxynitride, hafnium silicate, or other suitable dielectric material, is deposited over the entire structure including the cap layer 14, the exposed sidewalls of the silicon fin 12, and the surface of the buried oxide layer 10.

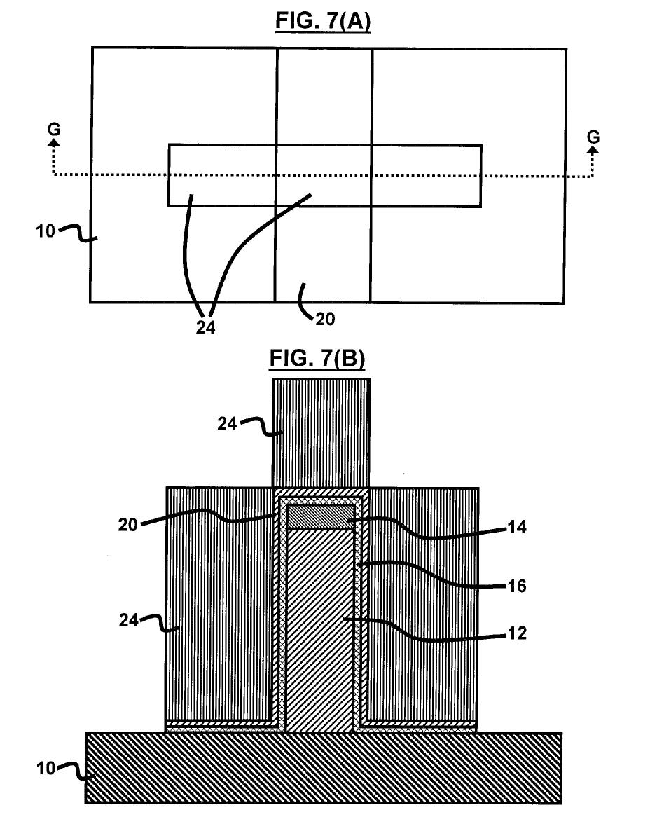

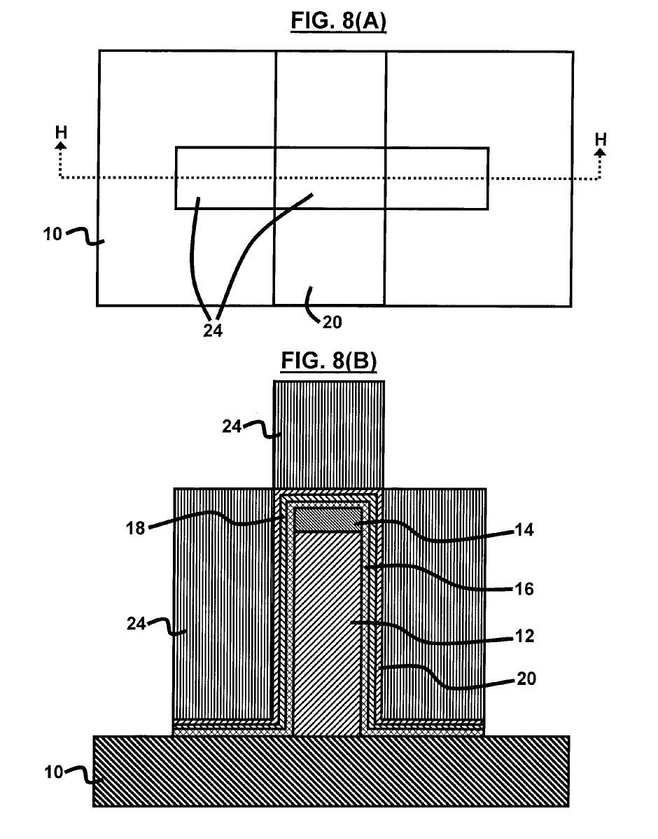

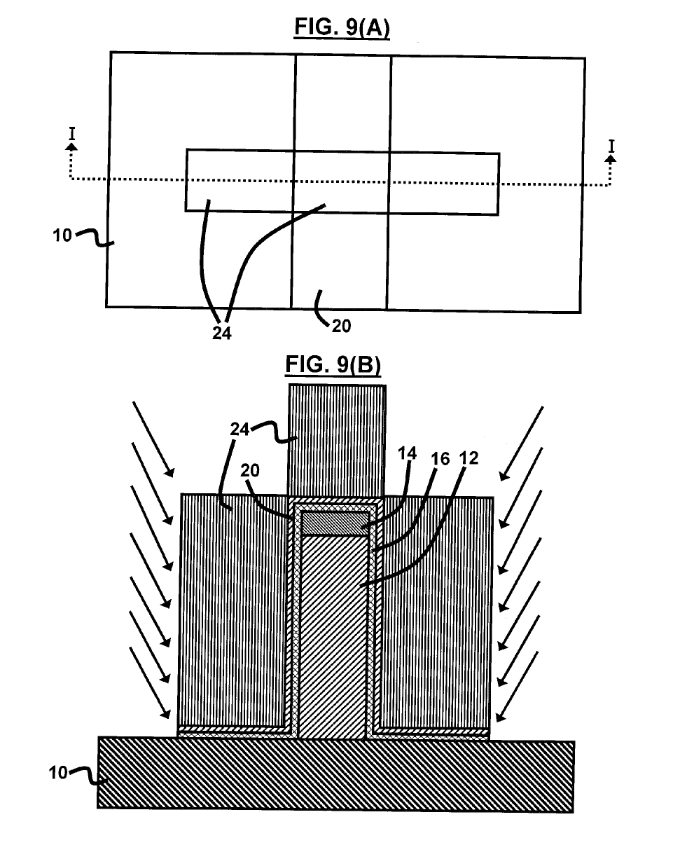

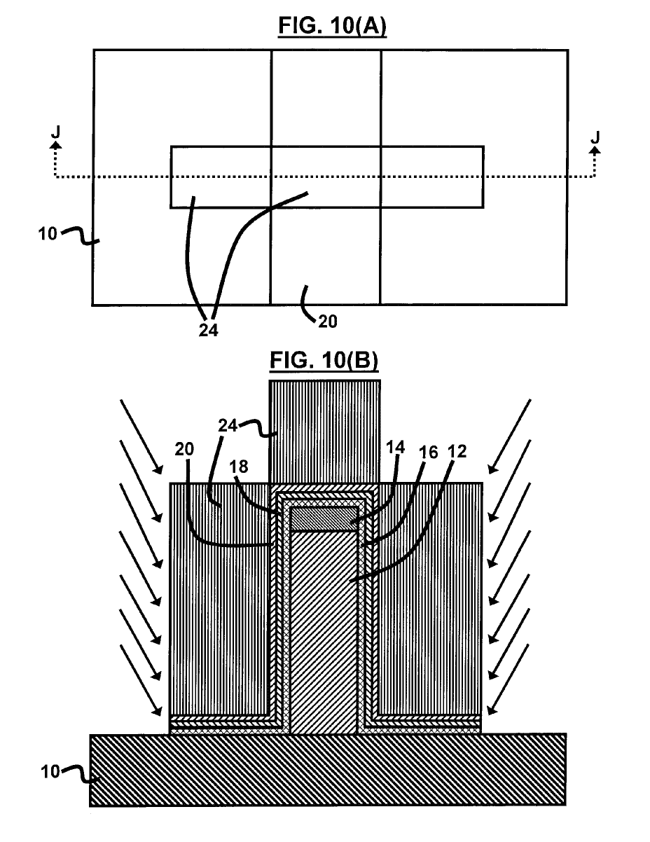

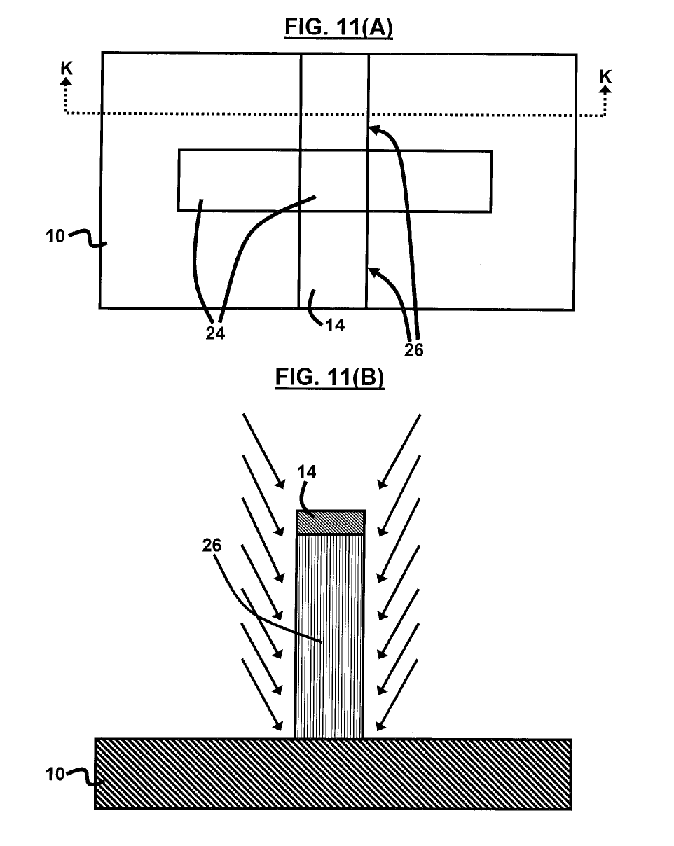

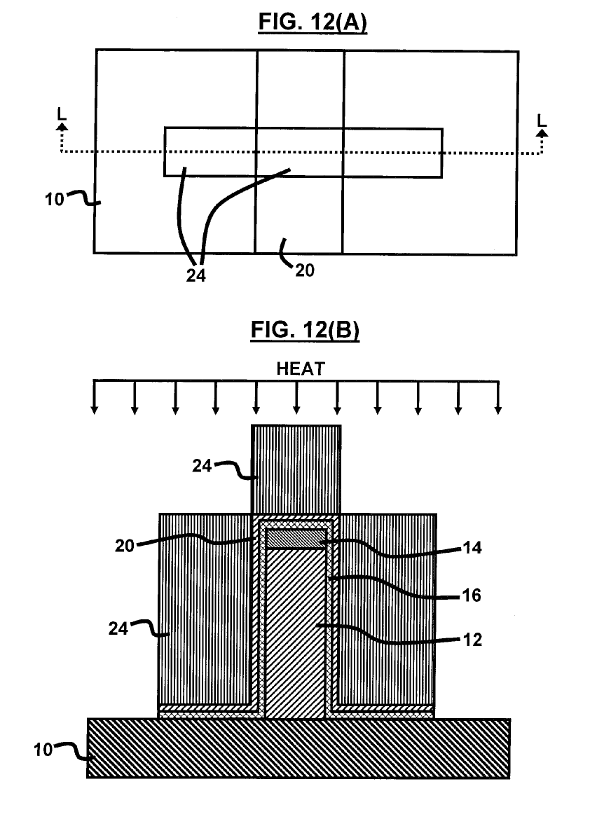

As illustrated in FIGS. 3(A) and 3(B) an outer metal layer 20 of approximately 1-10 nm in thickness, such as a catalyst metal including cobalt, nickel or iron, is deposited over the entire structure. In a second embodiment, an inner metal layer 18, such as Re, TaN, W, Ru, Pt, Rh, doped polycrystalline silicon or any other conductor, which has the proper work function for the operable FinFET threshold voltage range, is deposited over the entire structure and then the outer metal layer 20 is deposited over the inner metal layer 18, as depicted in FIGS. 4(A) and 4(B).

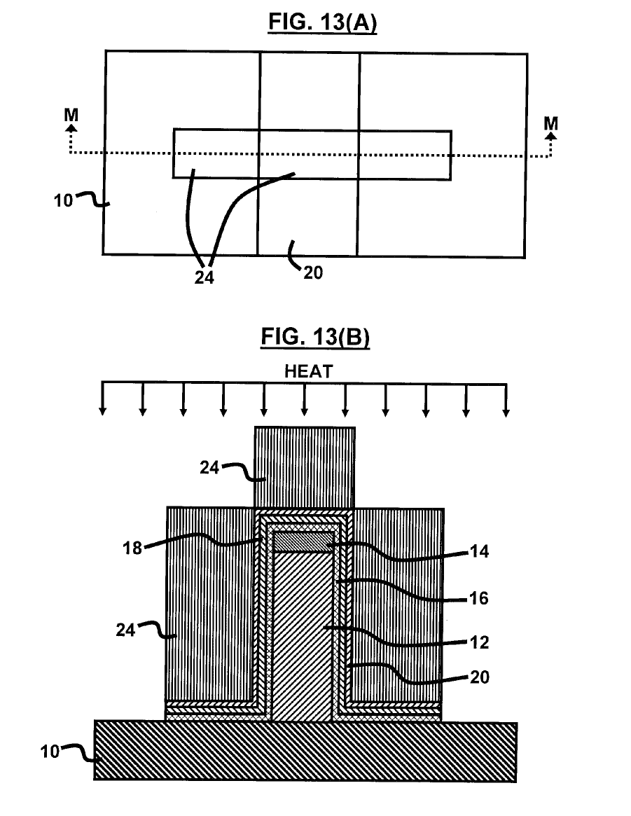

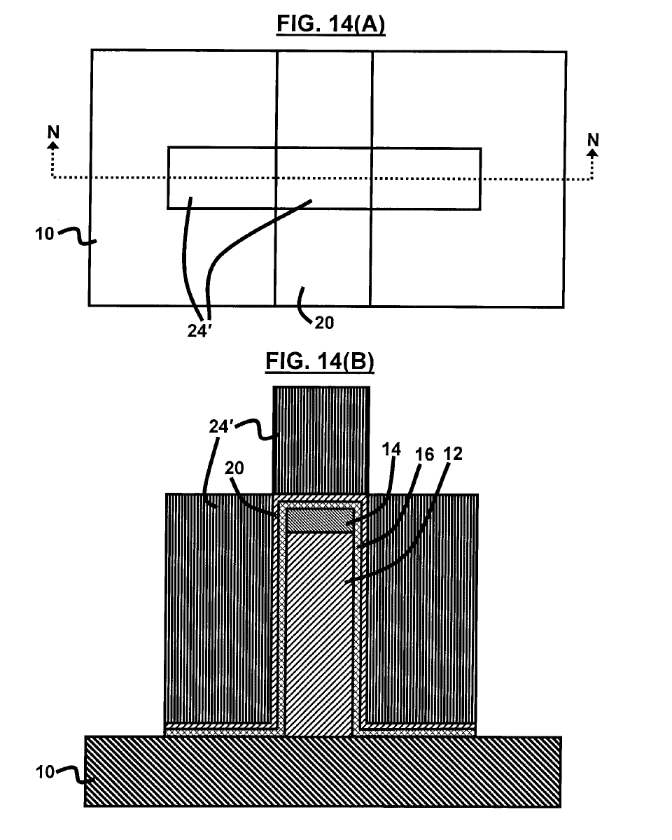

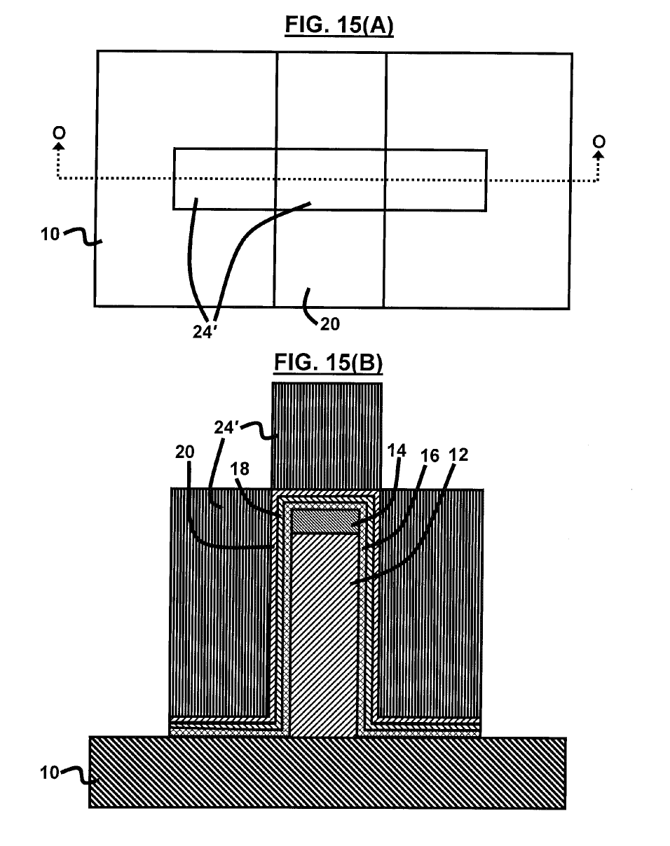

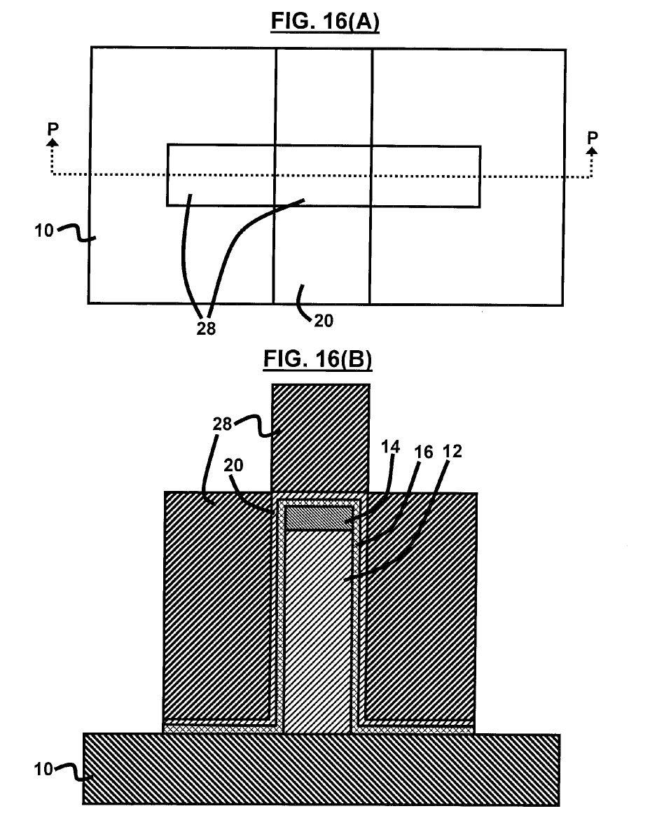

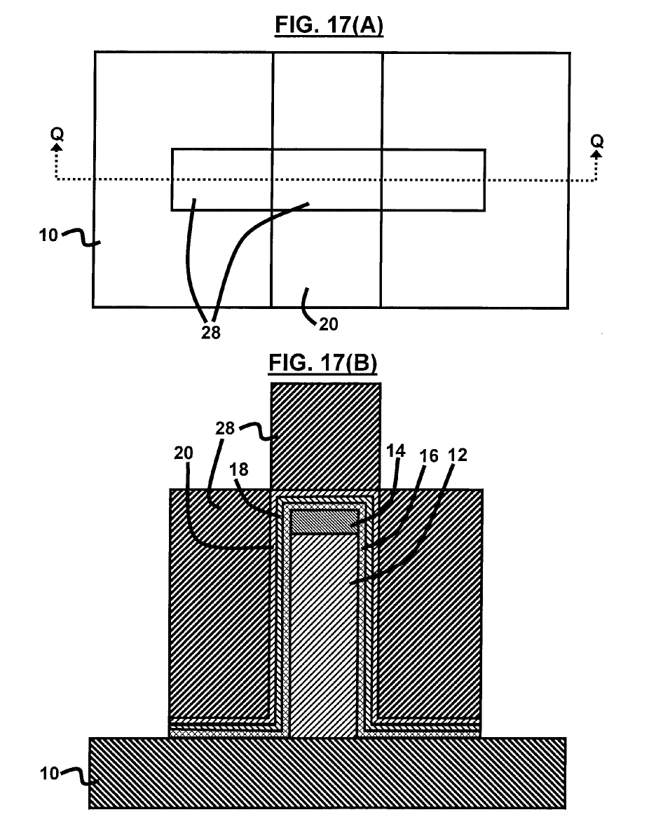

FIGS. 5(A) through 6(B) illustrate a patterning and etching process, whereby a photoresist mask 22 is selectively formed over portions of the underlying structure thereby allowing for selective gate patterning of the FinFET structure. The patterning may be accomplished using an isotropic dry or wet etching process because the outer metal layer 20 or a composite of the inner metal layer 18 and outer metal layer 20 are relatively thin (approximately 1-10 nm). Furthermore, the isotropic etch will prevent significant degradation of the image uniformity. Thus, the patterning process removes exposed portions of the outer metal layer 20 according to the first embodiment (FIGS. 5(A) and 5(B)) or exposed portions of the inner metal layer 18 and the outer metal layer 20 according to the second embodiment (FIGS. 6(A) and 6(B)).

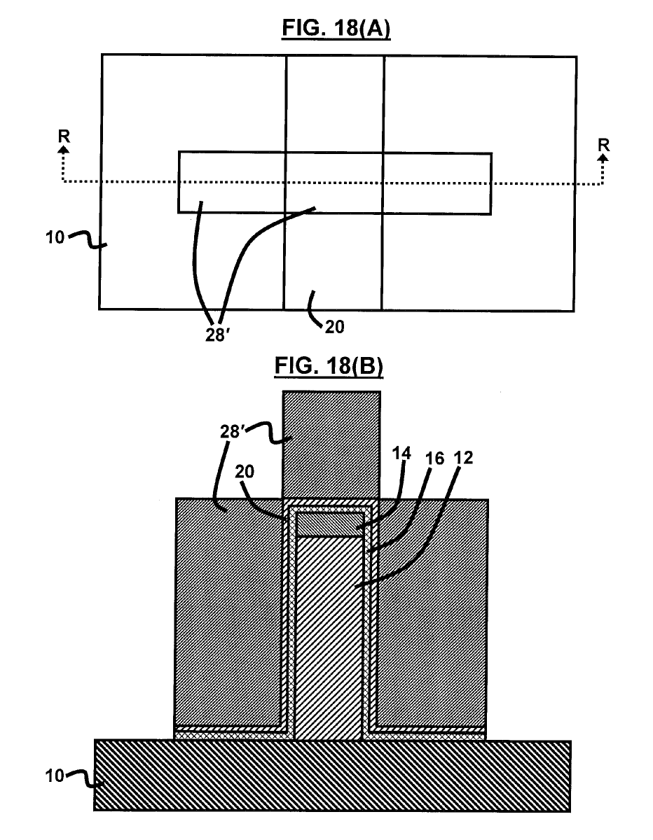

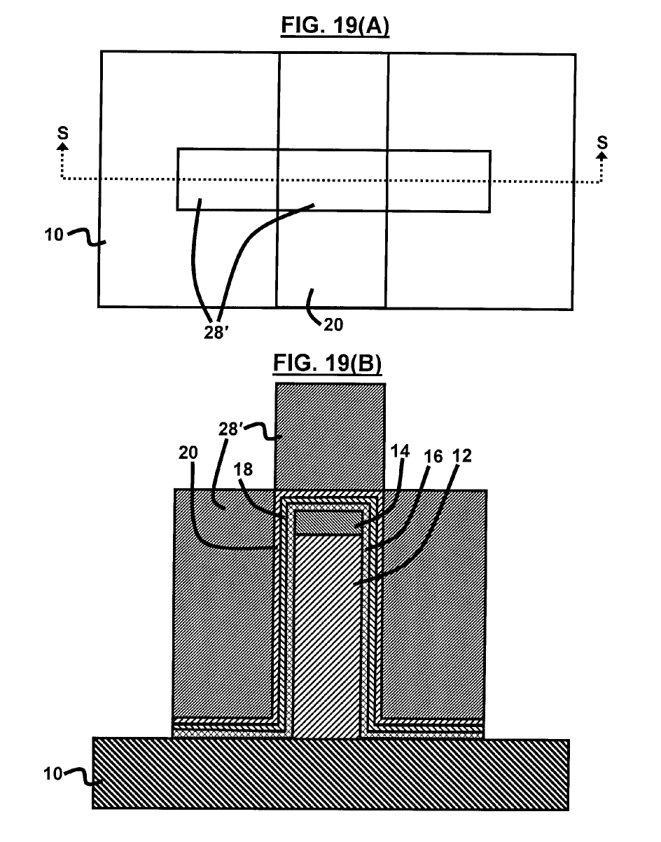

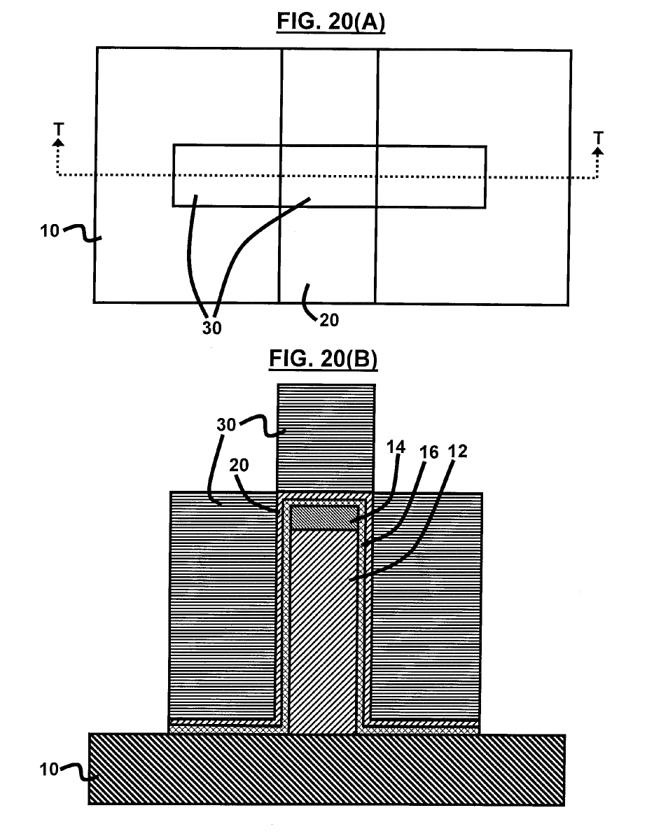

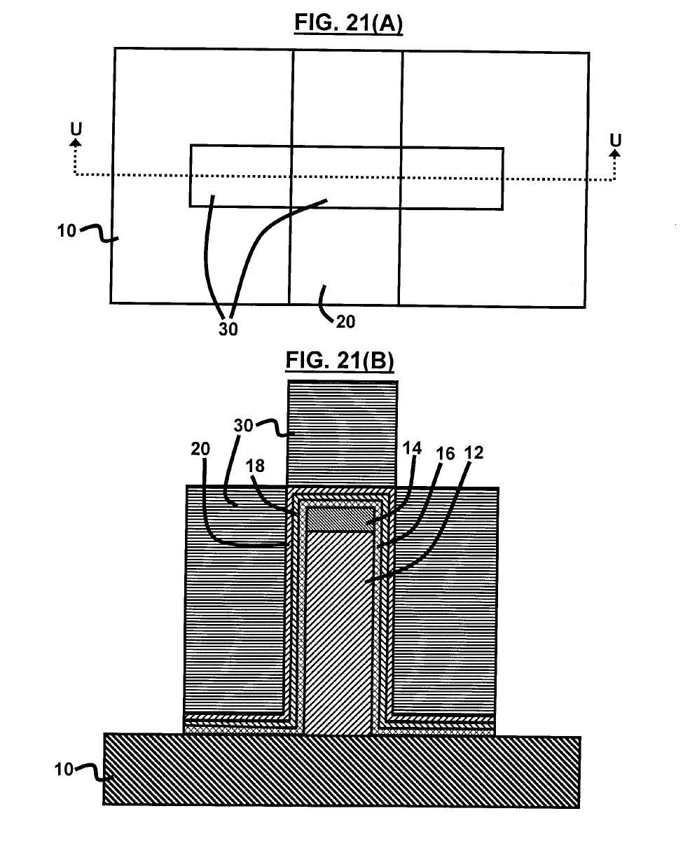

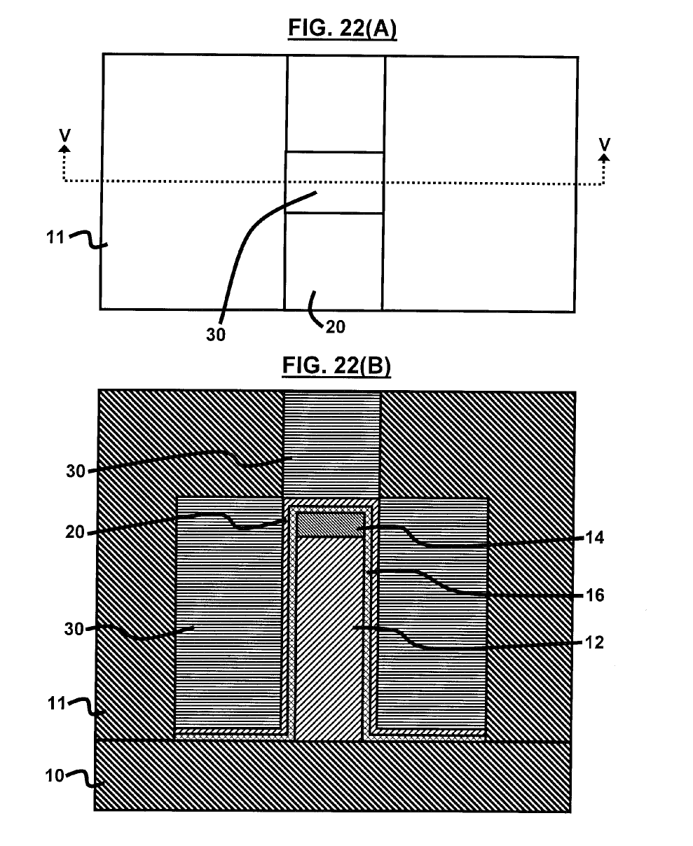

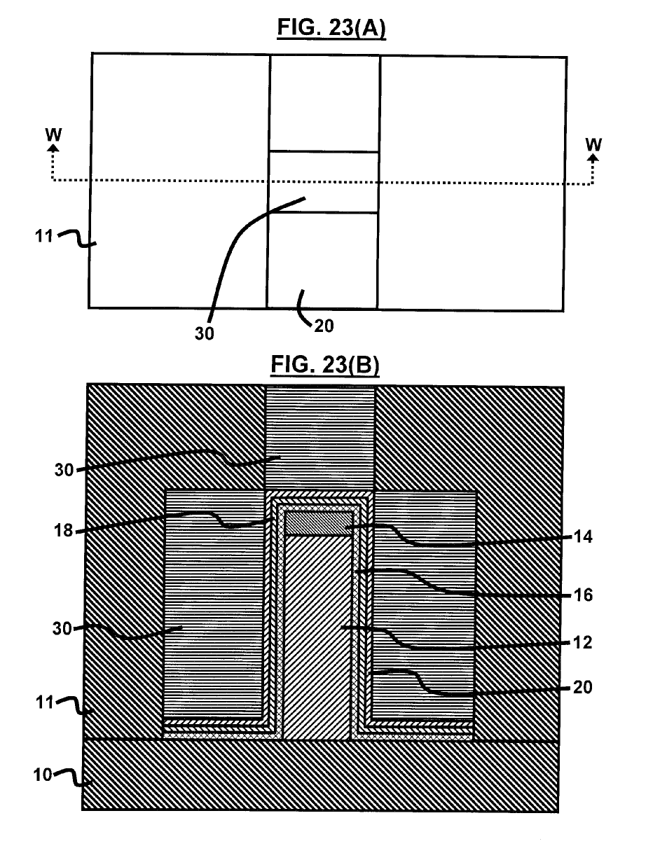

Next, carbon nanotubes 24 are grown from the surface of the outer metal layer 20 according to the first embodiment shown in FIGS. 7(A) and 7(B) or, alternatively, from the surface of the outer metal layer 20 according to the second embodiment shown in FIGS. 8(A) and 8(B). Preferably, the carbon nanotubes 24 are directionally grown at 800-900° C. in a chemical vapor deposition (CVD) furnace with a CO/H₂ mixture, methane, or acetylene (mixed with ammonia), whereby the carbon nanotubes 24 are grown to a length of approximately 30-200 nm depending on the product application. Following the growth of the carbon nanotubes 24, additional mass may be added to the open spaces between carbon nanotubes 24 using a polypyrole deposition if needed to improve implant-blocking characteristics or to offset subsequent implants away from incipient gate regions.

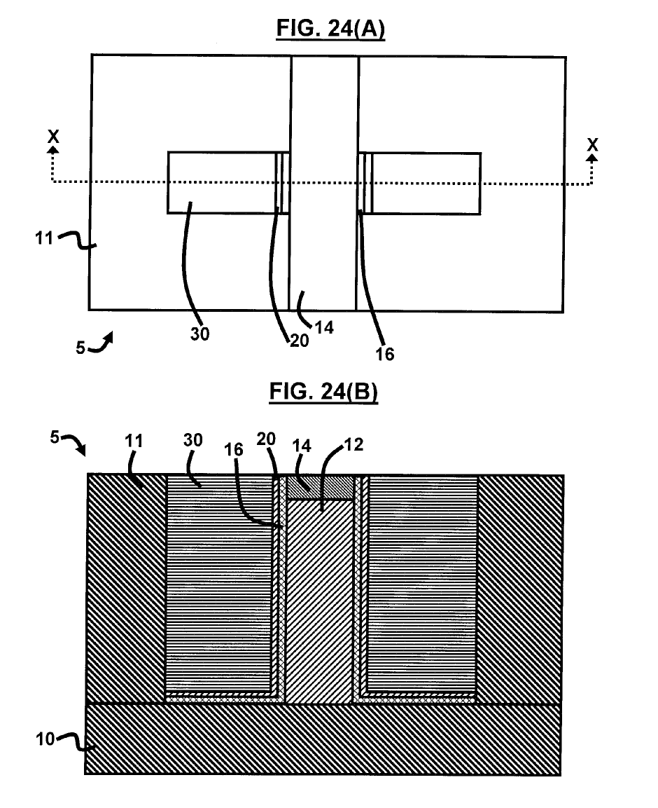

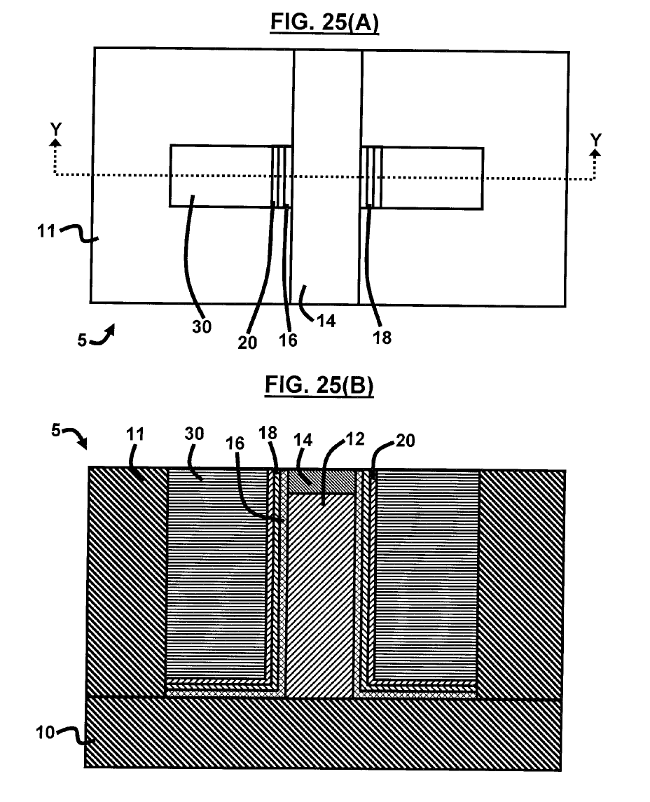

Thereafter, the wafer surface may be cleaned if needed. As shown in FIGS. 9(A) through 11 (B), a P³⁰ and N³⁰ source/drain ion implantation (I/I) is performed as denoted by the arrows in FIGS. 9(B) and 11 (B), using techniques well-known in the art. Specifically, a spin apply resist mask (not shown) is formed and selectively patterned. Implants create the N³⁰ regions. Thereafter, the resist is stripped in a liquid stripper or supercritical fluid so as not to damage the carbon nanotubes 24 during the resist strip process. Thereafter, another resist mask (not shown) is applied and the P+regions are formed by ion implantation. After the P³⁰ ion implantation, the resist is stripped in a liquid stripper or supercritical fluid so as not to damage the carbon nanotubes 24 during the resist strip process.

FIGS. 11(A) and 11(B) illustrate the formation of the source and drain regions 26 for both the first and second embodiments. The directional arrows in FIG. 11(B) generally indicate the source/drain ion implantation process. Next, as shown in FIGS. 12(A) through 13(B), heat is applied to the structure in a rapid thermal annealing process occurring at a temperature of approximately 1000° C. to 1100° C. for a few micro seconds to a few seconds, to activate the implanted dopants.

Thereafter, as illustrated in FIGS. 14(A) through 15(B), a carbon nanotube activation process occurs, thereby creating activated carbon nanotubes 24′. The activation process preferably occurs by introducing an upstream ammonia (NH₃) plasma or ammonia dissociated thermally with a heated filament to the structure and allowing a reaction to occur between the NH₃ plasma and carbon atoms of the carbon nanotubes 24 (of FIGS. 12(A) through 13(B)) to attach the amine groups to the surface of the carbon nanotubes 24 (of FIGS. 12(A) through 13(B)) thereby forming the structure shown in FIGS. 14(A) through 15(B). Alternatively, the activation process occurs by oxidizing the carbon nanotubes 24 (of FIGS. 12(B) and 13(B)) with an 0₂ plasma or a S/P (sulfuric acid/ hydrogen peroxide) cleaning process thereby creating the activated carbon nanotubes 24′ of FIGS. 14(A) through 15(B).

FIGS. 16(A) through 17(B) illustrate the next step in the fabrication process, whereby the structure is dipped into an aqueous solution. The aqueous solution may include a palladium salt, platinum salt, PtCI₂, nitrate salt, or any other appropriate metal salt that is capable of binding to the amine group of the carbon atoms associated with the activated carbon nanotubes 24′ (of FIGS. 14(B) and 15(B)). This dipping process creates a metal ion layer 28 over the carbon nanotubes 24′ (of FIGS. 14(B) and 15(B)).

Upon completion of this step, the process continues by reducing the metal ion layer 28 by exposing it with H₂ gas at approximately 25° C., thereby reducing the metal ion layer 28 to a seed metal layer 28′, as depicted in FIGS. 18(A) through 19(B). Then, the seed metal layer 28′ is plated with a desired metal 30 such as Pt, Pd, Co, Ni, Ru, Rh, Cu, W, etc. to enhance conductivity, as shown in FIGS. 20(A) through 21(B). Alternatively, the plated metal 30 can be allowed to mushroom over the oxide 10 to form a T gate for better conductivity. Next, a silicon oxide layer 11 is deposited over the device followed by a planarization of the entire device as shown in FIGS. 22(A) through 25(B). Preferably, the device 5 is planarized to the level of the cap layer 14 and to the level of the plated metal 30 formed over the activated carbon nanotubes 24′ (of FIGS. 14(A) through 15(B)), which are formed along the sidewall portions of the outer metal layer 20 (in both the first and second embodiments).

The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

Generally, as illustrated in FIGS. 1(A) through 25(B), the embodiments of the invention provide a FinFET gate 5 comprising a semiconductor wafer (BOX layer 10 +silicon fin 1 2), which is preferably embodied as a silicon on insulator wafer; a gate dielectric layer 16 over the semiconductor wafer (BOX layer 10 +silicon fin 12); a conductive material on the gate dielectric layer 16 (the conductive material may comprise a first metal layer 20 over the gate dielectric layer 16 or a second metal layer 18 disposed between the first metal layer 20 and the gate dielectric layer 16); an activated carbon nanotube 24′ on the surface of the conductive material 20; and a plated metal layer 30 on the activated carbon nanotube 24′. In another embodiment, a second metal layer 18 is formed under the conductive material 20. Preferably, the carbon nanotube 24′ is grown on a sidewall of the conductive material 20. The first metal layer 20 preferably acts as a catalyst for growing a carbon nanotube 24, and wherein the first metal layer 20 is preferably in a range of 1-10 nm in thickness. The first metal layer 20 may comprise any of Co, Ni, and Fe, and the second metal layer 18 may comprise any of Re, TaN, W, Ru, Pt, Rh, and doped polycrystalline silicon.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of preferred embodiments, those skilled in the art will recognize that the embodiments of the invention can be practiced with modification within the spirit and scope of the appended claims.

What is claimed is:

1. A fin field effect transistor (FinFET) gate comprising:
a semiconductor wafer;
a gate dielectric layer over said semiconductor wafer;
a conductive material on said gate dielectric layer;
an activated carbon nanotube on a surface of said conductive material; and
a plated metal layer on said activated carbon nanotube.

2. The FinFET gate of claim 1, wherein said carbon nanotube is on a sidewall of said conductive material.

3. The FinFET gate of claim 1, wherein said conductive material comprises a first metal layer over said gate dielectric layer, wherein said first metal layer acts as a catalyst for growing said carbon nanotube.

4. The FinFET gate of claim 3, wherein said first metal layer is in a range of 1-10 nm in thickness.

5. The FinFET gate of claim 1, wherein said semiconductor wafer comprises a silicon on insulator wafer.

6. The FinFET gate of claim 3, further comprising a second metal layer disposed between said first metal layer and said gate dielectric layer.

7. The FinFET gate of claim 6, wherein said first metal layer comprises any of Co, Ni, and Fe, and wherein said second metal layer comprises any of Re, TaN, W, Ru, Pt, Rh, and doped polycrystalline silicon.

8. A transistor device comprising:
a semiconductor wafer;
a gate dielectric layer over said semiconductor wafer;
a conductive material on said gate dielectric layer;
an activated carbon nanotube on a surface of said conductive material;
a seed metal layer on said activated carbon nanotube; and
a plated metal layer on said seed metal layer.

9. The device of claim 8, wherein said carbon nanotube is on a sidewall of said conductive material.

10. The device of claim 8, wherein said conductive material comprises a first metal layer over said gate dielectric layer, wherein said first metal layer acts as a catalyst for growing said carbon nanotube.

11. The device of claim 10, wherein said first metal layer is in a range of 1-10 nm in thickness.

12. The device of claim 8, wherein said semiconductor wafer comprises a silicon on insulator wafer.

13. The device of claim 10, further comprising a second metal layer disposed between said first metal layer and said gate dielectric layer.

14. The device of claim 13, wherein said first metal layer comprises any of Co, Ni, and Fe, and wherein said second metal layer comprises any of Re, TaN, W, Ru, Pt, Rh, and doped polycrystalline silicon.

15. A method of forming a gate structure for a semiconductor device, said method comprising:
forming a gate dielectric layer over a semiconductor wafer;
depositing a conductive material on said gate dielectric layer;
growing a carbon nanotube on a surface of said conductive material;
activating said carbon nanotube;
attaching metal ions to the activated carbon nanotube;
forming a seed metal layer on said activated carbon nanotube by chemically reducing said metal ions; and
plating metal on said seed metal layer.

16. The method of claim 15, wherein said carbon nanotube is formed on a sidewall of said conductive material.

17. The method of claim 15, wherein said conductive material comprises a first metal layer over said gate dielectric layer, wherein said first metal layer acts as a catalyst for growing said carbon nanotube.

18. The method of claim 17, wherein said first metal layer is in a range of 1-10 nm in thickness.

19. The method of claim 17, further comprising forming a second metal layer between said first metal layer and said gate dielectric layer.

20. The method of claim 19, wherein said first metal layer comprises any of Co, Ni, and Fe, and wherein said second metal layer comprises any of Re, TaN, W, Ru, Pt, Rh, and doped polycrystalline silicon.
